(19) United States
(12) Patent Application Publication
(10) Pub. No.: US 2007/0166458 A1
(43) Pub. Date: Jul. 19, 2007

(54) Vaporizer for cvd, solution-vaporization type cvd apparatus and vaporization method for cvd

(75) Inventor: Hisayoshi Yamoto, Nagareyama-shi (JP)

Correspondence Address: EDWARDS ANGELL PALMER & DODGE LLP, P.O. BOX 55874, BOSTON, MA, 02205, US

(73) Assignee: YOUTEC CO.,Ltd., Chiba (JP)

(21) Appl. No.: 10/584,726

(22) PCT Filed: Mar. 17, 2004
(86) PCT No.: PCT/JP04/06633

§ 371 Date: Jun. 23, 2006

(30) Foreign Application Priority Data
Dec. 26, 2003 (JP) 2003-432566

(51) Int. Cl. C23C 16/00

(52) U.S. Cl. 427/248.1; 118/715; 118/726

(57) ABSTRACT

The present invention relates to a vaporizer for CVD, a solution-vaporization type CVD apparatus and a vaporization method for CVD which suppress clogging of a solution pipe or the like and extend continuous operation times. A vaporizer for CVD of the present invention comprises a plurality of raw-material solution pipes which respectively supply a plurality of raw-material solutions separately from one another, a carrier gas pipe disposed in such a manner as to surround the exteriors of the raw-material-solution pipes and allows the pressurized carrier gas to flow to the exterior of each of the plurality of raw-material-solution pipes, an orifice provided in the leading end of the carrier gas pipe, and spaced away from the leading ends of the raw-material-solution pipes, a vaporization tube connected to the leading end of the carrier gas pipe and led to the interior of the carrier gas pipe via the orifice, and a heater which is heating means for heating the vaporization tube.

### BACKGROUND OF THE INVENTION

1. Field of the Invention

The present invention relates to a vaporizer for CVD, a solution-vaporization type CVD apparatus and a vaporization method for CVD, and more particularly, a vaporizer for CVD, a vaporization method for CVD and a solution-vaporization type CVD apparatus using the CVD vaporizer which suppress clogging of a solution pipe or the like and extend continuous operation times.

2. Description of the Related Art

In CVD technologies adopted by semiconductor industries from around 1970, to form a thin film, a reactant in a gaseous state is introduced into a reactor, and a chemical reaction is caused, thereby forming a thin film with various compositions on a semiconductor substrate made of silicon or the like. The CVD technologies, however, has a limitation that a thin film cannot be formed by CVD unless a gaseous reactant is prepared.

At IEDM (International Electron Devices Meeting) of 1987, W. I. KINNEY et al. announced a technology for fabricating a high speed nonvolatile memory FeRAM (FRAM: Ferroelectric Random Access Memory) by utilizing the polarization phenomenon of a ferroelectric material (like PZT, or SBT). At that time, a thin film of a ferroelectric material like PZT, or SBT could not be formed by CVD because preparation of a gaseous chemical containing Zr, Sr, Bi was impossible. Accordingly, a solution coating method similar process to photo resist thing film formation was applied to fabrication of a FeRAM. There is a problem such that a ferroelectric material thin film (thickness: 400-300 nm) formed by the solution coating method, has a poor step coverage, and thinning of the film (thickness: 150-40 nm) causes increment of the number of pin holes, thereby decreasing an electrical isolation. For practical application of a FeRAM-LSI which has a plurality of steps and requires thinning of a ferroelectric material (thickness: 100-50 nm), a technology which fabricates a high-quality ferroelectric thin film by CVD is necessary.

In 1992, Dr. Shiozaki, an assistant professor in the engineering Dept. at Kyoto University, formed a ferroelectric thin film PZT by CVD and announced this world's first formation at an academic conference. A CVD apparatus adopted by Dr. Shiozaki employed a scheme of sublimating and gasifying a solid chemical.

The scheme of sublimating and gasifying a solid chemical, however, has following problems. That is, it is difficult to increase a flow rate of a reactant because a rate of sublimation when sublimating a solid chemical is low and, because of the difficulty of flow rate control of the reactant, a deposition rate of a thin film is low, resulting in a poor reproducibility. Further, it is difficult to carry the sublimated chemical to a reactor with a pipe heated at approximately 250° C.

In order to make an additional experiment on the technique announced by Dr. Shiozaki, the inventor of the present invention purchased the same CVD apparatus used by Dr. Shiozaki from the same manufacturer with Dr. Shiozaki's assistance, and performed a film formation experiment. Immediately after starting operation of the CVD apparatus, however, a high-temperature pipe was clogged. After fixed, the high-temperature pipe was then heated extraordinary. Based on such an experience, the inventor concluded that a technology of evenly heating thin, long stainless pipes (external diameter: ¼ inch and length: 1 m of several pipes) with a plurality of valves disposed on the middle portions thereof at 250±5° C. is extremely difficult.

Based on the above-described experience, the inventor concluded that it is difficult to put the sublimation type CVD apparatus to practical use. Consequently, the inventor succeeded the world's first deposition of a high-quality thin film of a ferroelectric material SBT by employing a solution-vaporization CVD method (so-called flash CVD method). He announced this success at an international academic conference, ISIF '96 (“Performance of SrBi₂Ta₂O₉ Thin Films Grown by Chemical Vapor Deposition for Nonvolatile Memory Applications”. C. Isobe, H. Yamoto, H. Yagi et al. 9^{th} International Symposium on Integrated Ferroelectrics. March, 1996), and first verified the possibility of commercialization of a ferroelectric memory FeRAM around the world.

As a vaporizer for producing a reaction gas for SBT thin film synthesis formation by dissolving solid material in solvent so as to produce solution and gasifying the solution at a high temperature, one made by ATMI Inc. was initially adopted. This vaporizer, however, could not be adopted by a CVD apparatus for mass production because it was clogged in a matter of ten hours. Accordingly, in 1996, the inventor placed an order with Mr. Yoshioka of Shimadzu Corporation and Dr. Toda, a professor of Material Engineering dept. of Faculty of Engineering at Yamagata University to develop and manufacture a high-performance solution supply control system and a high performance vaporizer necessary for stably forming a high-quality SBT thin film. A developed and delivered apparatus (solution supply control system and vaporizer), however, had the following problem, and it was difficult to stably form a SBT thin film. Meanwhile, this apparatus (solution supply control system and vaporizer) is disclosed in Patent Literature 1 (Japanese Unexamined Patent Publication No. 2000-216150) and Patent Literature 2 (Japanese Unexamined Patent Publication No. 2002-105646).

As a reactant for synthesizing a SBT thin film, Sr(DPM)₂, BiPh₃, Ta(OEt)₅, Sr[Ta(OEt)₅(OC₂H₄OMe)]₂, Bi(OtAm)₃, Bi(MMP)₃, and the like. are used, and particularly, using Sr[Ta(OEt)₅(OC₂H₄OMe)]₂+Bi(MMP)₃ makes it possible to perform high-speed deposition (5-100 nm/min) at 320-420° C., thereby enabling formation of a high-quality SBT thin film having good step coverage and electrical property. The above apparatus (solution supply control system and vaporizer), however, was clogged immediately when Sr[Ta(OEt)₅(OC₂H₄OMe)]₂+Bi(MMP)₃ was used as a reactant chemical. When the inventor researched and examined the reason of clogging, he found the reason why is that when solution of Sr[Ta(OEt)₅(OC₂H₄OMe)]₂+Bi(MMP)₃ was mixed at a room temperature, Sr[Ta(OEt)₅(OC₂H₄OMe)]₂ and Bi(MMP)₃ reacted with each other and a material which had a small solubility and was unlikely to sublimate was synthesized, thereby clogging a path for allowing the solutions to flow and the leading end of a vaporization tube. This phenomenon will now be explained in detail.

FIG. 4 is a TG CHART (Ar 760/10 Torr, O₂ 760 Toor) of Sr[Ta(OEt)₅(OC₂H₄OMe)]₂. This figure illustrates: a graph 101 representing changes in the weight of a sample of Sr[Ta(OEt)₅(OC₂H₄OMe)]₂ when the sample is undergone temperature rise from 30 to 600° C. at a rate of 10° C./min. under argon atmosphere at a pressure of 760 Torr and a flow rate of 100 ml/min., a graph 102 representing changes in the weight of the sample when it is undergone temperature rise from 30 to 600° C. at a rate of 10° C./min. under argon atmosphere at a pressure of 10 Torr and a flow rate of 50 ml/min., and a graph 103 representing changes in the weight of the sample when it is undergone temperature rise from 30 to 600° C. at a rate of 10° C./min. under oxygen atmosphere at a pressure of 760 Torr and a flow rate of 100 ml/min. It can be seen from the figure that Sr[Ta(OEt)₅(OC₂H₄OMe)]₂ completely sublimes at approximately 220° C. under argon atmosphere at a pressure of 10 Torr.

FIG. 5 is a TG CHART (Ar 760/10 Torr, O₂ 760 Toor) of Bi(OtAm)₃. This figure illustrates a graph 111 representing changes in the weight of a sample of Bi(OtAm)₃ when the sample is undergone temperature rise from 30 to 600° C. at a rate of 10° C./min. under argon atmosphere at a pressure of 760 Torr and a flow rate of 100 ml/min., a graph 112 representing changes in the weight of the sample when it is undergone temperature rise from 30 to 600° C. at a rate of 10° C./min. under argon atmosphere at a pressure of 10 Torr and a flow rate of 50 ml/min., and a graph 113 representing changes in the weight of the sample when it is undergone temperature rise from 30 to 600° C. at a rate of 10° C./min. under oxygen atmosphere at a pressure of 760 Torr and a flow rate of 100 ml/min. It can be seen from the figure that approximately 98% of Bi(OtAm)₃ sublimes at approximately 130° C. under argon atmosphere at a pressure of 10 Torr.

FIG. 6 is a TG CHART (Ar 760/10 Torr, O₂ 760 Toor) of Bi(MMP)₃. This figure illustrates a graph 121 representing changes in the weight of a sample of Bi(MMP)₃ when the sample is undergone temperature rise from 30 to 600° C. at a rate of 10° C./min. under argon atmosphere at a pressure of 760 Torr and a flow rate of 100 ml/min., a graph 122 representing changes in the weight of the sample when it is undergone temperature rise from 30 to 600° C. at a rate of 10° C./min. under argon atmosphere at a pressure of 10 Torr and a flow rate of 50 ml/min., and a graph 123 representing changes in the weight of the sample when it is undergone temperature rise from 30 to 600° C. at a rate of 10° C./min. under oxygen atmosphere at a pressure of 760 Torr and a flow rate of 100 ml/min. It can be seen from the figure that Bi(MMP)₃ completely sublimes at approximately 150° C. under argon atmosphere at a pressure of 10 Torr.

FIG. 7 is a TG CHART (Ar 760/10 Torr, O₂ 760 Toor) of a mixture of Bi(OtAm)₃/Sr[Ta(OEt)₆]₂. This figure illustrates a graph 131 representing changes in the weight of a sample of Bi(OtAm)₃/Sr[Ta(OEt)₆]₂ when the sample is undergone temperature rise from 30 to 600° C. at a rate of 10° C./min. under argon atmosphere at a pressure of 760 Torr and a flow rate of 100 ml/min., and a graph 133 representing changes in the weight of the sample when it is undergone temperature-rise from 30 to 600° C. at a rate of 10° C./min. under oxygen atmosphere at a pressure of 760 Torr and a flow rate of 100 ml/min. It can be seen from the figure that only 80% of the mixture of Bi(OtAm)₃/Sr[Ta(OEt)₆]₂ sublimes under argon atmosphere even if it is heated at greater than or equal to 300° C.

As explained, both Sr[Ta(OEt)₅(OC₂H₄OMe)]₂ and Bi(OtAm)₃ almost completely sublime in individuals, but when they mixed with each other, a part of them do not sublime. The deterioration of a sublimation characteristic may cause clogging of the vaporizer.

A reason for the deterioration of the sublimation characteristic can be seen from NMR characteristic (Nuclear Magnetic Resonance of H) as illustrated in FIG. 8. When Bi(OtAm)₃ and Sr[Ta(OEt)₆]₂ are mixed, a new NMR characteristic is observed, and this represents that a new chemical compound is formed and is in presence.

FIG. 9 is a TG CHART (Ar 760 Torr) of a mixture of Bi(MMP)₃/Sr[Ta(OEt)₅(OC₂H₄OMe)]₂. This figure illustrates a graph representing changes in the weight of a sample of Bi(MMP)₃/Sr[Ta(OEt)₅(OC₂H₄OMe)]₂ when the sample is undergone temperature rise from 30 to 600° C. at a rate of 10° C./min. under argon atmosphere at a pressure of 760 Torr and a flow rate of 100 ml/min. It can be seen from the figure that only 80% of the mixture of Bi(MMP)₃/Sr[Ta(OEt)₅(OC₂H₄OMe)]₂ sublimes under argon atmosphere.

FIG. 10 is a TG CHART (Ar 760/10 Torr, O₂ 760 Toor) of BiPh₃. This figure illustrates a graph 141 representing changes in the weight of a sample of BiPh₃ when the sample is undergone temperature rise from 30 to 600° C. at a rate of 10° C./min. under argon atmosphere at a pressure of 760 Torr and a flow rate of 100 ml/min., a graph 142 representing changes in the weight of the sample when it is undergone temperature rise from 30 to 600° C. at a rate of 10° C./min. under argon atmosphere at a pressure of 10 Torr and a flow rate of 50 ml/min., and a graph 143 representing changes in the weight of the sample when it is undergone temperature rise from 30 to 600° C. at a rate of 10° C./min. under oxygen atmosphere at a pressure of 760 Torr and a flow rate of 100 ml/min. It can be seen from the figure that 100% of BiPh₃ sublimes at approximately 200° C.

FIG. 11 is a TG CHART (Ar 760/10 Torr, O₂ 760 Toor) of BiPh₃/Sr[Ta(OEt)₆]₂ mixture. This figure illustrates a graph 151 representing changes in the weight of a sample of BiPh₃/Sr[Ta(OEt)₆]₂ mixture when the sample is undergone temperature rise from 30 to 600° C. at a rate of 10° C./min. under argon atmosphere at a pressure of 760 Torr and a flow rate of 100 ml/min., and a graph 153 representing changes in the weight of the sample when it is undergone temperature rise from 30 to 600° C. at a rate of 10° C./min. under oxygen atmosphere at a pressure of 760 Torr and a flow rate of 100 ml/min. It can be seen from the figure that almost 100% of BiPh₃/Sr[Ta(OEt)₆]₂ mixture sublimes at approximately 280° C.

FIG. 12 illustrates NMR characteristics and mixing stabilities of BiPh₃ and Sr[Ta(OEt)₆]₂. No synthesis of a new material is observed in a mixture of BiPh₃/Sr[Ta(OEt)₆]₂.

FIG. 13 is a TG-DTA CHART (O₂ 760 Torr) of BiPh₃. As illustrated in the figure, the oxidation reaction of BiPh₃ occurs at 465° C. It can be seen that because the oxidizing temperature of BiPh₃ is so high with respect to 259° C. of Sr[Ta(OEt)₅(OC₂H₄OMe)]₂, 209° C. of Bi(MMP)₃, and 205° C. of Bi(OtAm)₃, it is difficult to adopt BiPh₃.

Bi(OtAm)₃ causes a hydrolysis reaction with only 180 ppm of moisture. This shows that Bi(OtAm)₃ is immeasurably more sensitive to moisture than Sr[Ta(OEt)₅(OC₂H₄OMe)]₂ causing a hydrolysis reaction with 1650 ppm of moisture, and Bi(MMP)₃ causing that reaction with 170 ppm of moisture, and treatment of Bi(OtAm)₃ is difficult. Since moisture is certainly in presence, a possibility that Bi(OtAm)₃ reacts with moisture and formed Bi oxide clogs up a pipe, a flow meter, and the like may increase.

Patent Literature 1: Japanese Unexamined Patent Publication No. 2002-216150 (paragraphs 76 to 78, paragraphs 145 to 167, FIG. 3, and FIG. 8)

Patent Literature 2: Japanese Unexamined Patent Publication No. 2002-105646 (paragraphs 13 to 14, and FIG. 2) The problems of the conventional technologies described above can be summarized as follows.

The technology of gasifying a solid chemical by sublimation at a room temperature and using this gas as a reactive gas has a problem such that a deposition rate of thin film is low and varies, whereby it may be difficult to put it in practical use.

In contrast, the solution-vaporization type CVD method using a solid chemical at a room temperature, dissolving the solid chemical in a solvent, atomizing it, and then vaporizing it at high temperature, has a high deposition rate of thin film, but, there is a phenomenon that a chemical reaction occurs in a solution state, thereby clogging up a solution pipe or the like. As the solution-pipe or the like is clogged, the CVD apparatus can be continuously operated for short times. Therefore, this makes it necessary that a solution supplying system be devised.

The present invention has been made in view of the foregoing circumstances, and it is an object of the present invention to provide a vaporizer for CVD, a solution-vaporization type CVD apparatus, and a vaporization method for CVD which suppress clogging of a solution pipe or the like and extend continuous operation times.

### SUMMARY OF THE INVENTION

To achieve the object, a vaporizer for CVD oc the invention comprises

a dispersion unit which disperses a plurality of raw-material solutions into a carrier gas in a fine particulate or misty form,

a plurality of raw-material-solution passages which respectively supply the plurality of raw-material solutions, separately from one another, to the dispersion unit,

a carrier gas passage which supplies the carrier gas to the dispersion unit separately from each of the plurality of raw-material solutions,

a vaporization unit which vaporizes the plurality of raw-material solutions dispersed by the dispersion unit, and

an orifice which is connected to the vaporization unit and the dispersion unit and through which the plurality of raw-material solutions dispersed by the dispersion unit are introduced into the vaporization unit.

As the vaporizer for CVD has the plurality of raw-material-solution passages, it is possible to provide the dispersion unit with the plurality of raw-material solutions separately from each other. This prevents the plurality of raw-material solutions from causing a chemical reaction in solution states, and clogging in the raw-material solution passages.

In the vaporizer for CVD, it is preferable that the dispersion unit should be disposed between the orifice and individual leading ends of the plurality of raw-material-solution passages, and the orifice should have a diameter smaller than a diameter of each of the plurality of raw-material-solution passages and a diameter of the carrier gas passage.

In the vaporizer for CVD, it is preferable that when the raw-material solutions are vaporized, the vaporization unit should become a depressurized state and the dispersion unit should become a pressurized state.

A vaporizer for CVD of the invention comprises

a plurality of raw-material-solution pipes which respectively supply a plurality of raw-material solutions separately from one another,

a carrier gas pipe which is disposed in such a manner as to surround exteriors of the plurality of raw-material-solution pipes and allows a pressurized carrier gas to flow to the exterior of each of the plurality of raw-material-solution pipes,

an orifice provided in a leading end of the carrier gas pipe and spaced away from leading ends of the plurality of raw-material-solution pipes,

a vaporization tube connected to the leading end of the carrier gas pipe and led to an interior of the carrier gas pipe via the orifice, and

heating means for heating the vaporization tube.

As the vaporizer for CVD has the plurality of raw-material-solution passages, it is possible to provide the dispersion unit with the plurality of raw-material solutions separately from each other. This prevents the plurality of raw-material solutions from causing a chemical reaction in solution states, and clogging in the raw-material solution passages. It is structured in such a way that the exteriors of the plurality of raw-material-solution pipes are wrapped by the carrier gas pipe and a carrier gas is allowed to flow to a space between the raw-material-solution pipes and the carrier gas is employed, and a vaporization tube for adiabatic expansion is provided on the downstream side of a flow. That is, as the pressurized carrier gas is allowed to flow to the space outward the raw-material-solution pipes, it is possible to suppress temperature rise at the raw-material-solution pipes and the carrier gas pipe. Therefore, because it is possible to suppress that only the solvent in the raw-material solution is vaporized between the orifice and the leading end of the raw-material-solution pipe, occurrence of a chemical reaction of the raw-material solutions is suppressed, and clogging at the orifice and the neighborhood thereof is suppressed.

In the vaporizer for CVD, the carrier gas and the plurality of raw-material solutions are mixed between the orifice in the carrier gas pipe and the leading ends of the plurality of raw-material-solution pipes, the plurality of raw-materials are dispersed into the carrier gas in a fine particulate or misty form, the dispersed fine particulate or misty raw-material solutions are introduced into the vaporization tube through the orifice and heated to vaporize by the heating means. Accordingly, it is suppressed that only a solvent in the raw-material solution vaporizes at the orifice or the vaporization tube near the orifice, this suppresses occurrence of a chemical reaction of the raw-material solutions, and clogging.

In the vaporizer for CVD, it is preferable that the orifice should have a diameter smaller than a diameter of each of the plurality of raw-material-solution pipes and a diameter of the carrier gas pipe.

In the vaporizer for CVD, it is possible that the plurality of raw-material solutions be a mixture of Sr[Ta(OEt)₅(OC₂H₄OMe)]₂ and a solvent and a mixture of Bi(MMP)₃ and a solvent, and the carrier gas be an argon gas or a nitrogen gas.

A solution-vaporization type CVD apparatus of the invention comprises any one of the vaporizers for CVD.

A solution-vaporization type CVD apparatus of the invention comprises

any one of the vaporizers for CVD, and

a reaction chamber connected to the vaporization tube,

wherein deposition is carried out with the plurality of raw-material solutions vaporized in the vaporization tube.

A vaporization method for CVD of the invention comprises supplying a plurality of raw-material solutions and a carrier gas to a dispersion unit separately from one another, mixing the plurality of raw-material solutions and the carrier gas in the dispersion unit and dispersing the plurality of raw-material solutions into the carrier gas in a fine particulate or misty form, and vaporizing the raw-material solutions by adiabatic expansion immediately after dispersion.

In the vaporization method for CVD, it is preferable that the raw-material solutions should be dispersed in a fine particulate or misty form within one second after mixture of the raw-material solutions. This makes it possible to suppress that only a solvent in the raw-material solution vaporizes in the vaporization unit, and it is thus suppressed that the raw-material solutions cause a chemical reaction in the dispersion unit, thereby suppressing clogging of the dispersion unit and the orifice.

As explained, the invention provides a vaporizer for CVD, a solution-vaporization type CVD apparatus, and a vaporization method for CVD which suppress clogging of a solution pipe or the like and extend continuous operation times.

### BRIEF DESCRIPTION OF THE DRAWINGS

FIG. 1A is a structural diagram exemplarily illustrating the solution supply system of a vaporizer for CVD according to the first embodiment of the present invention, FIG. 1B is a cross-sectional view exemplarily illustrating the solution supply system, a dispersion unit, and a vaporization unit, FIG. 1C is a structural diagram exemplarily illustrating the solution supply system of a vaporizer for CVD according to a second embodiment, and FIG. 1D is a structural diagram exemplarily illustrating the solution supply system of a vaporizer for CVD according to a third embodiment;

FIG. 2 is a diagram illustrating an experimental result of formation of an SBT thin film by continuously operating a solution-vaporization type CVD apparatus having a vaporizer for CVD of the first embodiment;

FIG. 3 is a diagram illustrating the result of an experiment which formed an SBT thin film by continuous operation of the solution-vaporization type CVD apparatus and measured the compositions of Bi, Ta, and Sr in the SBT thin film;

FIG. 4 is a TG CHART (Ar 760/10 Torr, O₂ 760 Toor) of Sr[Ta(OEt)₅(OC₂H₄OMe)]₂;

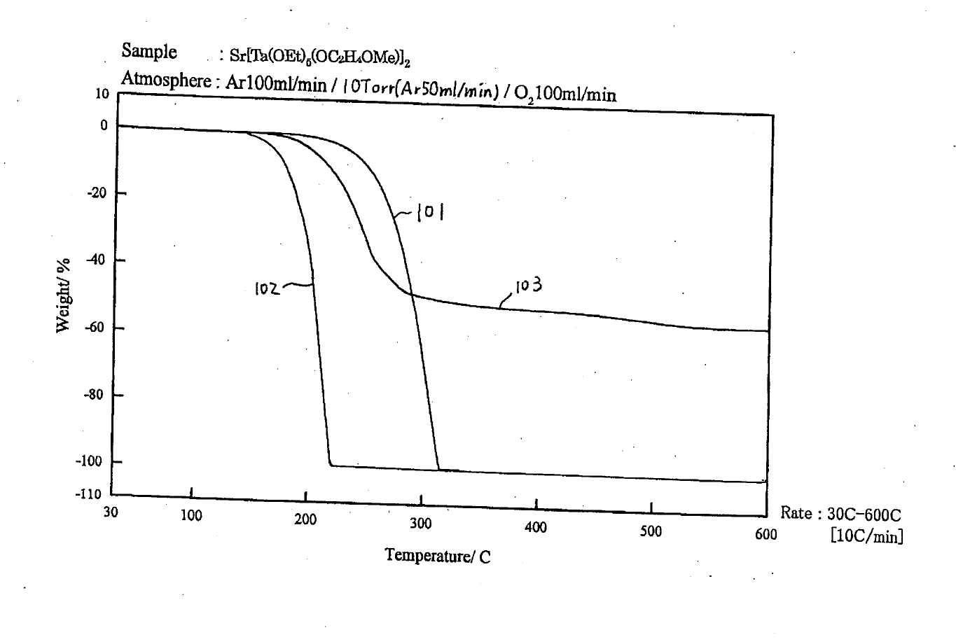

FIG. 5 is a TG CHART (Ar 760/10 Torr, O₂ 760 Toor) of Bi(OtAm)₃;

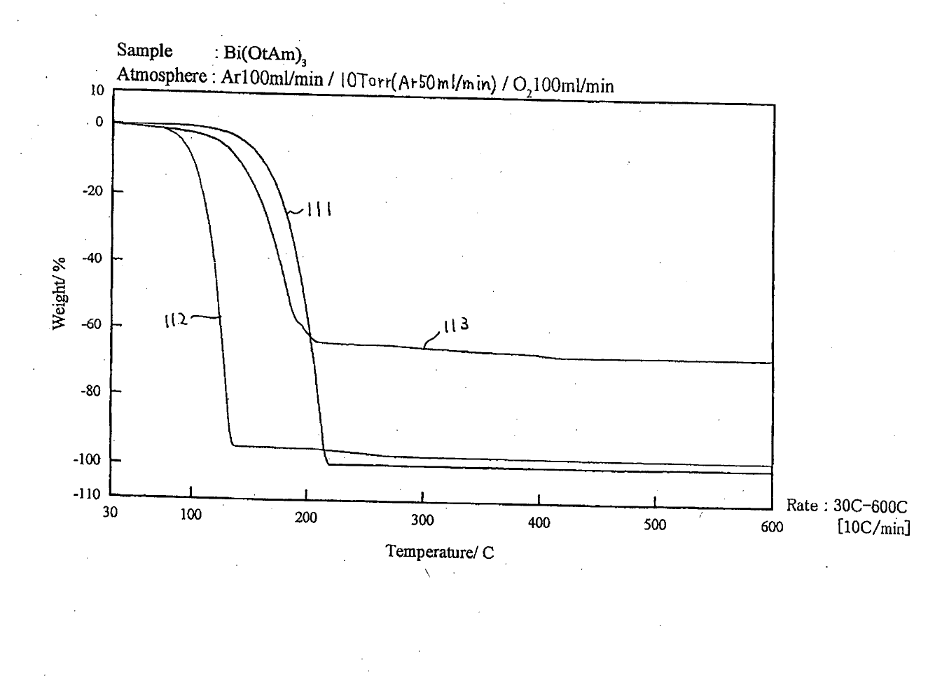

FIG. 6 is a TG CHART (Ar 760/10 Torr, O₂ 760 Toor) of Bi(MMP)₃;

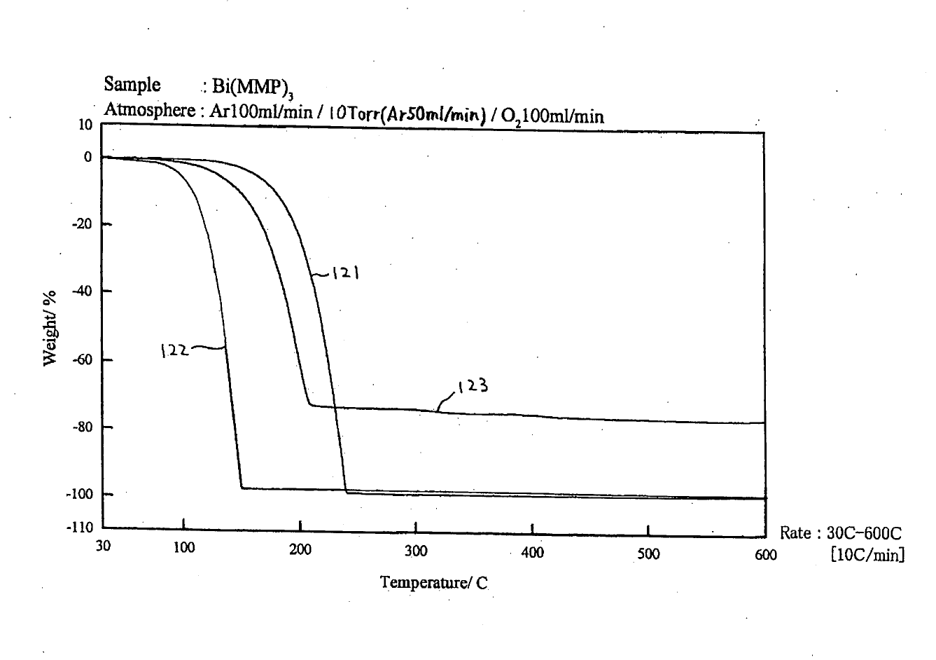

FIG. 7 is a TG CHART (Ar 760/10 Torr, O₂ 760 Toor) of the mixture of Bi(OtAm)₃/Sr[Ta(OEt)₆]₂;

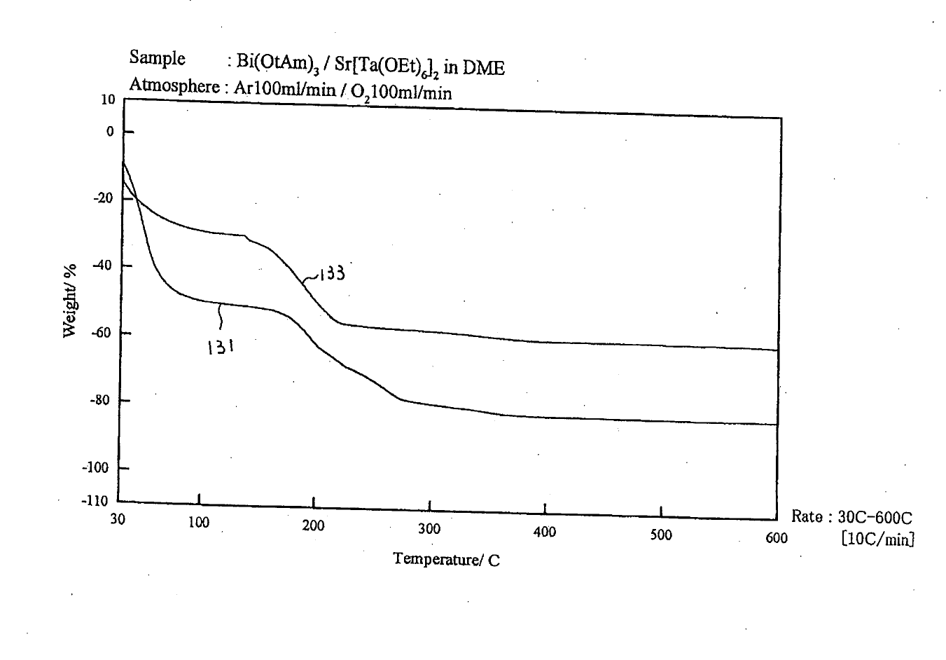

FIG. 8 a diagram illustrating NMR characteristic (nuclear magnetic resonance of H);

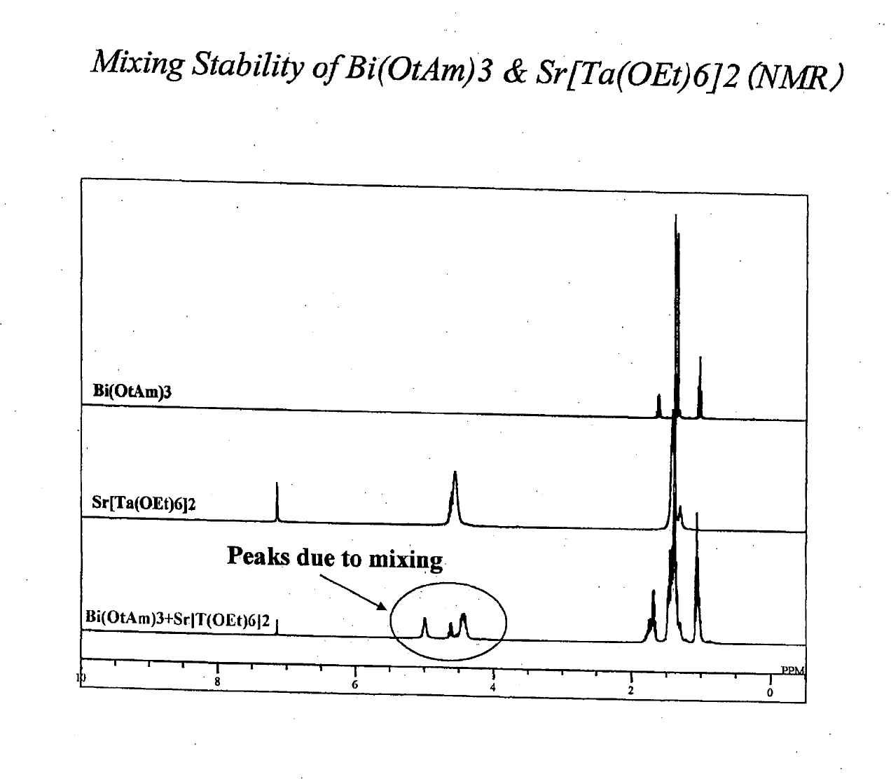

FIG. 9 is a TG CHART (Ar 760/10 Torr, O₂ 760 Toor) of the mixture of Bi(MMP)₃/Sr[Ta(OEt)₅(OC₂H₄OMe)]₂;

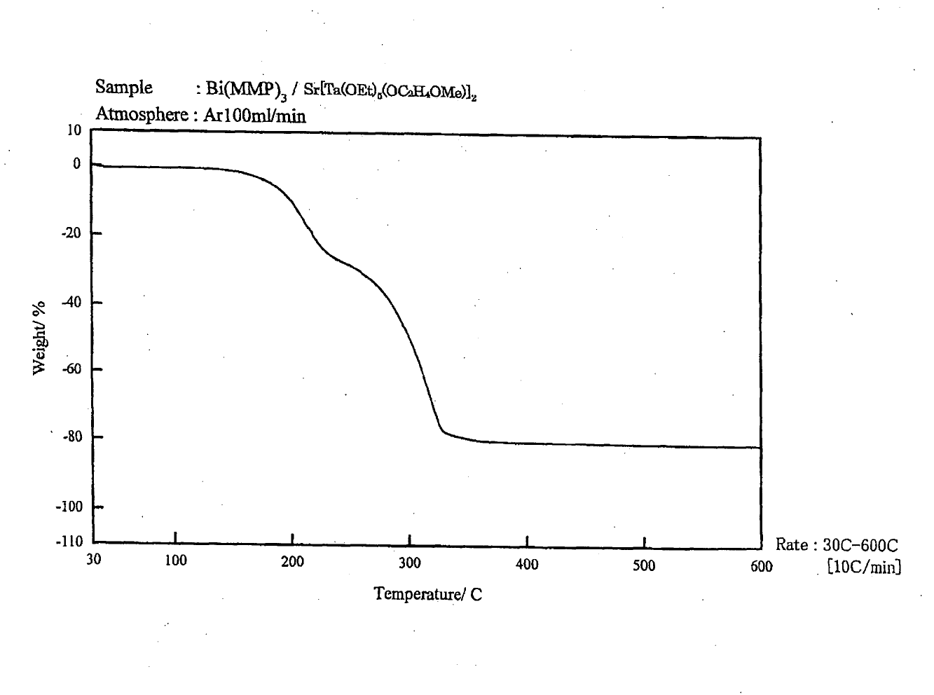

FIG. 10 is a TG CHART (Ar 760/10 Torr, O₂ 760 Toor) of BiPh₃;

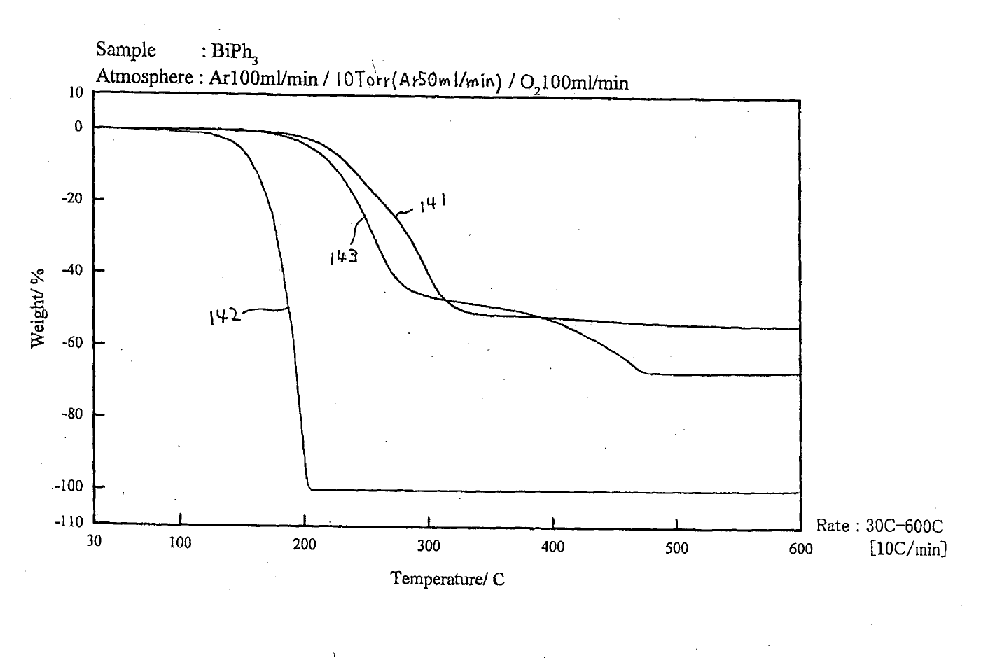

FIG. 11 is a TG CHART (Ar 760/10 Torr, O₂ 760 Toor) of BiPh₃/Sr [Ta(OEt)₆]₂;

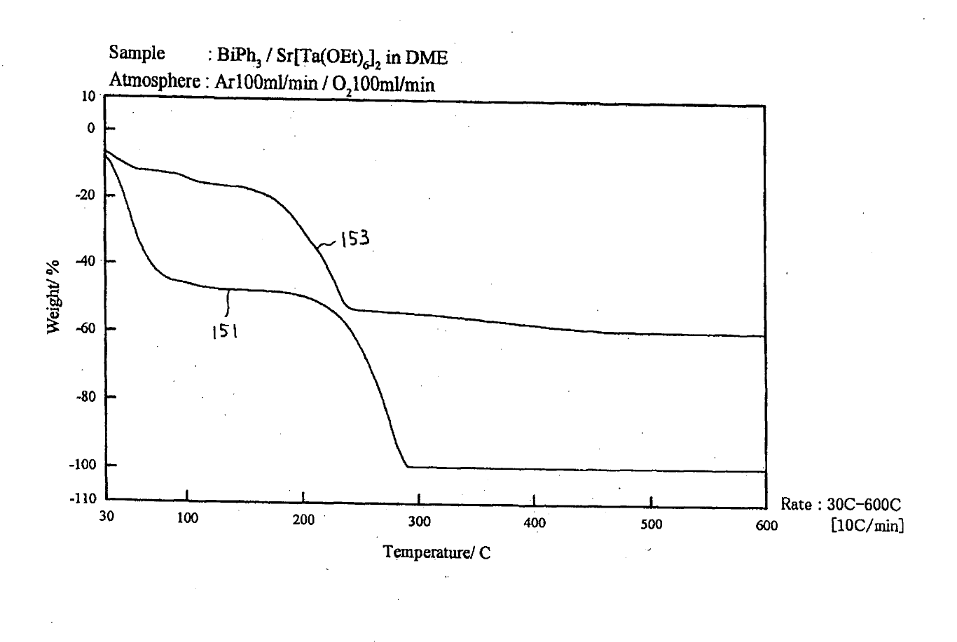

FIG. 12 is a diagram illustrating NMR characteristics representing mixing stabilities of BiPh₃ and Sr[Ta(OEt)₆]₂; and

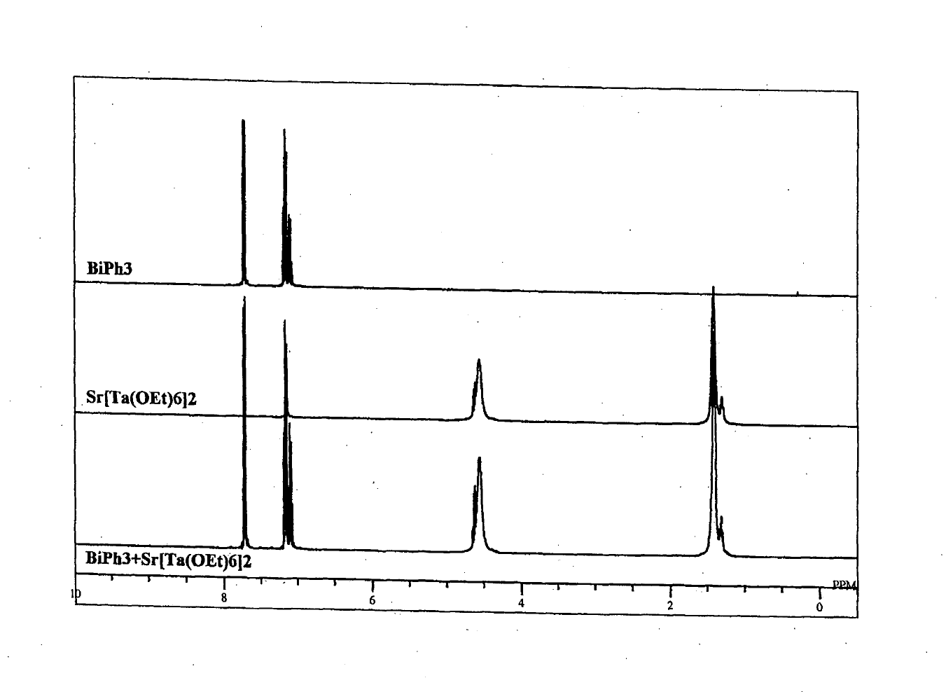

FIG. 13 is a TG-DTA CHART (O₂ 760 Torr) of BiPh₃.

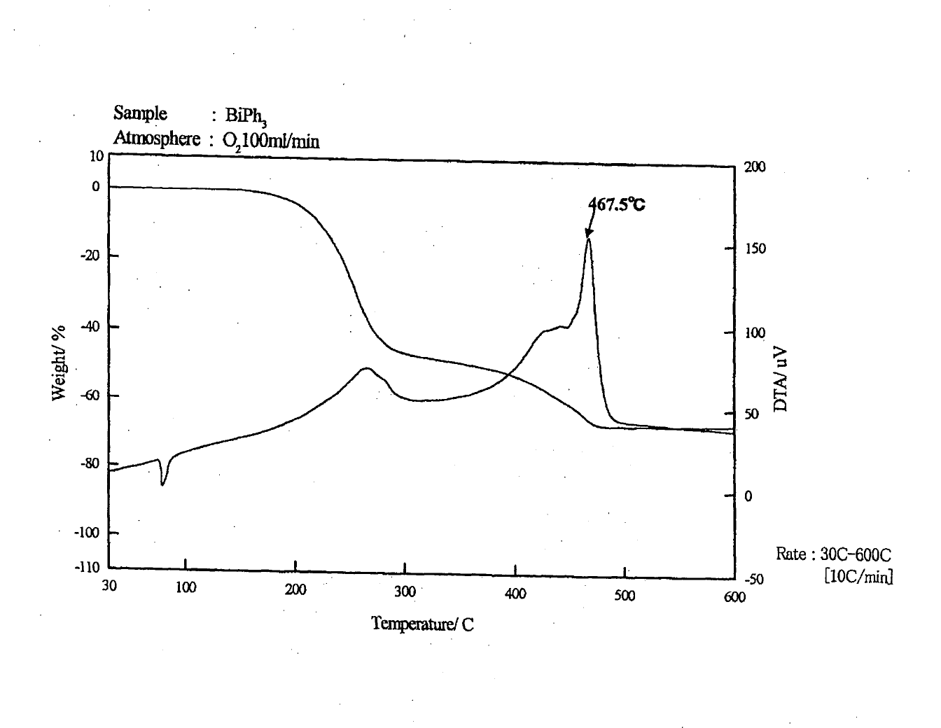

### DETAILED DESCRIPTION OF THE PREFERRED EMBODIMENTS

Preferred embodiments of the present invention will be explained with reference to the accompanying drawings.

### First Embodiment

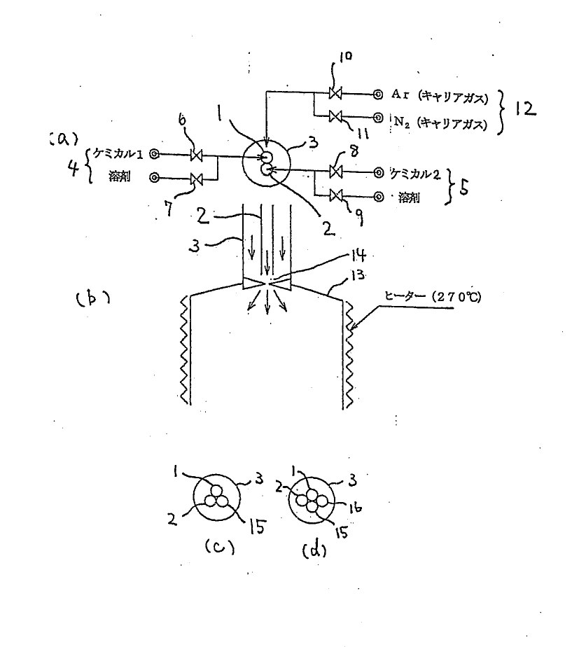

FIG. 1A is a structural diagram exemplarily illustrating the solution supply system of a vaporizer for CVD according to the first embodiment of the present invention, and FIG. 1B is a cross-sectional view exemplarily illustrating the solution supply system, a dispersion unit, and a vaporization unit.

As illustrated in FIGS. 1A and 1B, the vaporizer for CVD has first and second raw-material-solution pipes 1, 2. The first raw-material-solution pipe 1 is disposed adjacent to the second raw-material-solution pipe 2 in parallel therewith. A carrier gas pipe 3 is disposed outward the first and second raw-material-solution pipes 1, 2. The carrier gas pipe 3 is so formed as to have an internal diameter larger than the sum of the external diameter of the first pipe 1 and that of the second raw-material-solution pipe 2. That is, the first and second raw-material-solution pipes 1, 2 are inserted into the carrier gas pipe 3, and the pipe 3 is formed in such a manner as to wrap the first and second raw-material-solution pipes 1, 2.

The base end side of the first raw-material-solution pipe 1 is connected to a first supply mechanism 4 which supplies a chemical 1 and a solvent. The first supply mechanism 4 has a supply source which supplies the chemical 1 (for example, Sr[Ta(OEt)₅(OC₂H₄OMe)]₂), and a supply source which supplies the solvent. A valve 6 and a mass-flow controller (not illustrated) are provided between the supply source of the chemical 1 and the first raw-material-solution pipe 1. A valve 7 and a mass-flow controller (not illustrated) are provided between the supply source of the solvent and the first raw-material-solution pipe 1. The solvent and the chemical 1 flow into each other (mix) between the supply source of the solvent and the first raw-material-solution pipe 1.

The base end side of the second raw-material-solution pipe 2 is connected to a second supply mechanism 5 which supplies a chemical 2 and a solvent. The second supply mechanism 5 has a supply source which supplies the chemical 2 (for example, Bi(MMP)₃), and a supply source which supplies the solvent. A valve 8 and a mass-flow controller (not illustrated) are provided between the supply source of the chemical 2 and the second raw-material-solution pipe 2. A valve 9 and a mass-flow controller (not illustrated) are provided between the supply source of the solvent and the second raw-material-solution pipe 2. The solvent and the chemical 2 flow into each other (mix) between the supply source of the solvent and the second raw-material-solution pipe 2.

The base end side of the carrier gas pipe 3 is connected to a third supply mechanism 12 which supplies an argon gas and a nitrogen gas. The third supply mechanism 12 has a supply source which supplies the argon gas (Ar), and a supply source which supplies the nitrogen-gas (N₂). A valve 10 and a mass-flow controller (not illustrated) are provided between the supply source of the argon gas and the carrier gas pipe 3. A valve 11 and a mass-flow controller (not illustrated) are provided between the supply source of the nitrogen gas and the carrier gas pipe 3.

The leading end of the carrier gas pipe 3 is connected to one end of a vaporization tube 13. The carrier gas pipe 3 has an orifice formed in the leading end thereof, and the orifice connects the interior of the carrier gas pipe 3 and the interior of the vaporization tube 13. A heater provided around the vaporization tube 13 heats the vaporization tube 13 at, for example, 270° C. The other end of the vaporization tube 13 is connected to a non-illustrated reaction chamber.

Each of the leading ends of the first and second raw-material-solution pipes 1, 2 is spaced away from the orifice. That is, a dispersion unit 14 is provided between the individual leading ends of the first and second raw-material-solution pipes 1, 2 in the carrier gas pipe 3 and the orifice. The dispersion unit 14 mixes a first raw-material solution (one made by mixing the chemical 1 and the solvent thereof) which flows out of the leading end of the first raw-material-solution pipe 1 a second raw-material solution (one made by mixing the chemical 2 and the solvent thereof) which flows out of the leading end of the second raw-material-solution pipe 2 and the argon or nitrogen gas which flows out of the carrier gas pipe 3, and disperses the first and second raw-material solutions into the argon or nitrogen gas in a fine particulate or misty form.

Next, The operation of the aforementioned vaporizer for CVD will be explained.

First, the valve 6 is opened to supply the first raw-material solution from the first supply mechanism 4 to the first raw-material-solution pipe 1 by predetermined flow rate and pressure. The first raw-material solution is, for example, one made by mixing Sr[Ta(OEt)₅(OC₂H₄OMe)]₂ and the solvent thereof. The valve 8 is opened to supply the second raw-material solution from the second supply mechanism 5 to the second raw-material-solution pipe 2 by predetermined flow rate and pressure. The second raw-material solution is, for example, one made by mixing Bi(MMP)₃ and the solvent thereof. The valves 10, 11 are opened to supply the carrier gas from the third supply mechanism 12 to the carrier gas pipe 3 by predetermined flow rate and pressure. The carrier gas is, for example, the argon or nitrogen gas. A helium gas may be used.

Next, the first raw-material solution is supplied to the dispersion unit 14 through the first raw-material-solution pipe 1, the second raw-material solution is supplied to the dispersion unit 14 through the second raw-material-solution pipe 2, and the pressurized carrier gas is supplied to the dispersion unit 14 through the carrier gas pipe 3. The dispersion unit 14 mixes the first raw-material solution, the second raw-material solution and the carrier gas, and the first and second raw-material solutions are dispersed into the carrier gas in a fine particulate or misty form. It is preferable that the first and second raw-material solutions should be dispersed in a fine particulate or misty form within one second after mixed by the dispersion unit 14.

Next, the first and second raw-material solutions dispersed into the carrier gas by the dispersion unit 14 are introduced into the vaporization tube 13 through the orifice. In the vaporization tube 13, the first and second raw-material solutions dispersed in misty forms are instantaneously heated at approximately 270° C. by the heater.

There is a large difference between a pressure in the dispersion unit 14 and a pressure in the vaporization tube 13. The interior of the vaporizing portion 13 is in a reduced pressure state, while the interior of the dispersion unit 14 is in pressurized state. The pressure in the vaporizing portion 13 is, for example, 5 to 30 Torr, while the pressure in the dispersion unit 14 is, for example, 1500-2200 Torr. Setting such a pressure difference permits the carrier gas to jet toward the vaporization tube 13 at an ultrahigh speed, and expand (for example, adiabatic expansion) in accordance with the pressure difference. Accordingly, the sublimation temperature of chemicals contained in the first and second raw-material solutions is reduced, and thus the raw-material solutions (including the chemicals) can be vaporized by heat from the heater. Because the first and second raw-material solutions are turned to be fine mist by high speed flow of the carrier gas right after dispersed by the dispersion unit 14, they become likely to vaporize instantaneously in the vaporization tube 13.

The vaporizer for CVD vaporizes the first and second raw-material solutions, thereby forming a source gas in this manner. The source gas is fed to the reaction chamber through the vaporization tube 13, and a thin film is formed by a CVD method.

According to the foregoing first embodiment, the first and second raw-material-solution pipes 1, 2 are disposed in such a manner as to be adjacent to each other and in parallel with each other, and the carrier gas pipe 3 is disposed outward the first and second raw-material-solution pipes 1, 2, so that the first raw-material solution (Sr[Ta(OEt)₅(OC₂H₄OMe)]₂) and the second raw-material solution (Bi(MMP)₃) can be supplied separately form each other to the dispersion unit 14. This makes it possible to prevent the first and second raw-material solutions from causing a chemical reaction in solution states, thereby preventing clogging in the pipes. This extends the continuous operation time of the vaporizer for CVD.

In the embodiment, the respective exteriors of the first and second raw-material-solution pipes 1, 2 are wrapped by the carrier gas pipe 3 having a further large diameter, a structure that the carrier gas is allowed to flow to a space in between the first and second raw-material-solution pipes 1, 2 and the carrier gas pipe 3 is employed, and the high temperature vaporization tube is provided on the downstream side of the flow. Since the pressurized carrier gas is allowed to flow to the space outward the raw-material-solution pipes 1, 2 at a high speed (for example, the carrier gas is 200 ml/min. to 2L/min at 4 press.), temperature rise in the first and second raw-material-solution pipes 1, 2, the carrier gas pipe 3, and the dispersion unit 14 can be suppressed. Accordingly, in the raw-material-solution pipes 1, 2 and the dispersion unit 14, evaporation and vaporization of the solvent only in the raw-material solution can be suppressed, the raw-material solutions are concentrated in the raw-material-solution pipes 1, 2 and the dispersion unit 14, rising of a viscosity and a phenomenon that deposition occurs beyond the solubility are suppressed, thereby suppressing clogging of the raw-material-solution pipes 1, 2, the dispersion portion 14 and the orifice

According to the embodiment, as the first and second raw-material solutions are dispersed in a fine particulate or misty form immediately after (within one second) mixed with the carrier gas by the dispersion unit 14, it is possible to suppress that the raw-material solutions cause a chemical reaction in the dispersion unit 14, thus suppressing clogging of the dispersion unit 14 or the orifice. Therefore, the continuous operation time of the vaporizer for CVD can be extended.

Moreover, according to the embodiment, the first and second raw-material solutions are dispersed by the dispersion unit 14, and the dispersed raw-material solutions in the fine particulate or misty forms are heated in the vaporization tube 13 and can be vaporized (gasified) instantaneously. Therefore, because vaporization of the solvent only in the raw-material solution is suppressed at the orifice and the vaporization tube 13 near the orifice, it is possible to suppress that the raw-material solutions cause a chemical reaction at the orifice and the vaporization tube near the orifice, thereby suppressing clogging of the orifice or the vaporization tube 13 near the orifice. Therefore, the continuous operation time of the vaporizer for CVD can be extended.

As described above, according to the embodiment, by suppressing clogging of the pipes 1 to 3, the dispersion unit 14, the orifice and the vaporization tube 13, the vaporizer for CVD can be operated stably and continuously for a long time. Therefore, a thin film of a ferroelectric material, such as PZT, or SBT can be formed with a good reproducibility and a controllability, and this realizes high performance vaporizer for CVD and solution-vaporization type CVD apparatus.

### Second Embodiment

FIG. 1C is a structural diagram exemplarily illustrating the solution supply system of a vaporizer for CVD according to the second embodiment of the present invention, and the same structure portions as those illustrated in FIG. 1A will be denoted by the same reference numbers, and an explanation will be given of different portions only.

The vaporizer for CVD illustrated in FIG. 1C has three pipes 1, 2 and 15 for supplying three raw-material solutions. The first raw-material-solution pipe 1, the second raw-material-solution pipe 2 and the third raw-material-solution pipe 15 are so provided as to be adjacent to one another and in parallel with one another. The carrier gas pipe 3 is disposed outward the first to third raw-material-solution pipes 1, 2 and 15. That is, the first to third raw-material-solution pipes 1, 2 and 15 are inserted into the pipe 3, and the carrier gas pipe 3 is formed in such a manner as to wrap the first to third raw-material-solution pipes 1, 2 and 15.

The base end side of the third raw-material-solution pipe 15 is connected to a third supply mechanism (not illustrated) which supplies a chemical 3 and a solvent. The third supply mechanism has a supply source which supplies the chemical 3, and a supply source which supplies the solvent. A valve (not illustrated) and a mass-flow controller (not illustrated) are provided between the supply source of the chemical 3 and the third raw-material-solution pipe 15. A valve (not illustrated) and a mass-flow controller (not illustrated) are provided between the supply source of the solvent and the third raw-material-solution pipe 15. The solvent and the chemical 3 flow into each other (mix) between the supply source of the solvent and the third raw-material-solution pipe 15.

Each of the leading ends of the first to third raw-material-solution pipes 1, 2 and 15 are spaced away from the orifice. That is, a dispersion unit is formed between the respective leading ends of the first to third raw-material-solution pipes 1, 2 and 15 in the carrier gas pipe 3 and the orifice. The dispersion unit mixes the first raw-material solution (one made by mixing the chemical 1 and the solvent thereof) flows out of the leading end of the first raw-material-solution pipe 1, the second raw-material solution (one made by mixing the chemical 2 and the solvent thereof) flows out of the leading end of the second raw-material-solution pipe 2, a third raw-material solution (one made by mixing the chemical 3 and the solvent thereof) flows out of the leading end of the third raw-material-solution pipe 15, and the argon or nitrogen gas flows out of the carrier gas pipe 3, thereby dispersing the first to third raw-material solutions into the argon or nitrogen gas in a fine particulate or misty form.

The second embodiment can obtain the same effectiveness as that of the first embodiment.

### Third Embodiment

FIG. 1D is a structural diagram exemplarily illustrating the solution supply system of a vaporizer for CVD according to a third embodiment of the present invention, and the same structure portions as those illustrated in FIG. 1C will be denoted by the same reference numbers, and an explanation will be given of only different portions.

The vaporizer for CVD illustrated in FIG. 1D has four raw-material-solution pipes 1, 2, 15 and 16 which supply four raw-material solutions to the dispersion unit. The first raw-material-solution pipe 1, the second raw-material-solution pipe 2, the third raw-material-solution pipe 15 and the fourth raw-material-solution pipe 16 are disposed in such a manner as to be adjacent to one another and in parallel with one another. The carrier gas pipe 3 is disposed outward the first to fourth raw-material-solution pipes 1, 2, 15 and 16. That is, the first to fourth raw-material-solution pipes 1, 2, 15 and 16 are inserted into the carrier gas pipe 3, and the carrier gas pipe 3 is formed in such a manner as to wrap the first to fourth raw-material-solution pipes 1, 2, 15 and 16.

The base end of the fourth raw-material-solution pipe 16 is connected to a fourth supply mechanism (not illustrated) which supplies a chemical 4 and a solvent. The fourth supply mechanism has a supply source which supplies the chemical 4, and a supply source which supplies the solvent. A valve (not illustrated) and a mass-flow controller (not illustrated) are provided between the supply source of the chemical 4 and the fourth raw-material-solution pipe 16. A valve (not illustrated) and a mass-flow controller (not illustrated) are provided between the supply source of the solvent and the fourth raw-material-solution pipe 16. The solvent and the chemical 4 flow into each other (mix) between the supply source of the solvent and the fourth raw-material-solution pipe 16.

Each of the leading ends of the first to fourth raw-material-solution pipes 1, 2, 15 and 16 are spaced away from the orifice. That is, a dispersion unit is formed between the respective leading ends of the first to fourth pipes 1, 2, 15 and 16 in the carrier gas pipe 3 and the orifice. The dispersion unit mixes the first raw-material solution (one made by mixing the chemical 1 and the solvent thereof) flows out of the leading end of the first raw-material-solution pipe 1, the second raw-material solution (one made by mixing the chemical 2 and the solvent thereof) flows out of the leading end of the second raw-material-solution pipe 2, the third raw-material solution (one made by mixing the chemical 3 and the solvent thereof) flows out of the leading end of the third raw-material-solution pipe 15, a fourth raw-material solution (one made by mixing the chemical 4 and the solvent thereof) flows out of the leading end of the fourth raw-material-solution pipe 16, and the argon or nitrogen gas flows out of the carrier gas pipe 3, thereby dispersing the first to fourth raw-material solutions into the argon or nitrogen gas in a fine particulate or misty form.

The third embodiment can obtain the same effectiveness as that of the second embodiment.

The present invention is not limited to the aforementioned embodiments, and can be modified in various form without departing from the broad spirit and scope of the invention. For example, the range of application of the vaporizer for CVD, the vaporization method for CVD and the solution-vaporization type CVD apparatus of the invention is wide, is not limited toe formation of a high-quality ferroelectric thin film (for instance, SBT, PZT thin film) for a FeRAM-LSI which is a high speed nonvolatile memory, and a thin film of, for example, YBCO (Super Conductive Oxide), PZT/PLZT/SBT (Filter, MEMS, Optical Interconnect, HD), Metal (Ir, Pt, Cu), Barrier Metal (TiN, TaN), High k (HfOx, Al₂O₃, BST or the like) can be formed with CVD.

In the foregoing embodiments, the first raw-material solution which is made by dissolving Sr[Ta(OEt)₅(OC₂H₄OMe)]₂ in the solution thereof and the second raw-material solution which is made by dissolving Bi(MMP)₃ in the solution thereof are used, but not limited to this case, and a raw-material solution which is made by dissolving the other kind of a solid material in a solution thereof may be used. A liquid material of Sr[Ta(OEt)₅(OC₂H₄OMe)]₂ or the like itself may be used as a raw-material solution, and one made by mixing a liquid material with a solution may be used.

### EXAMPLES

Examples will now be explained

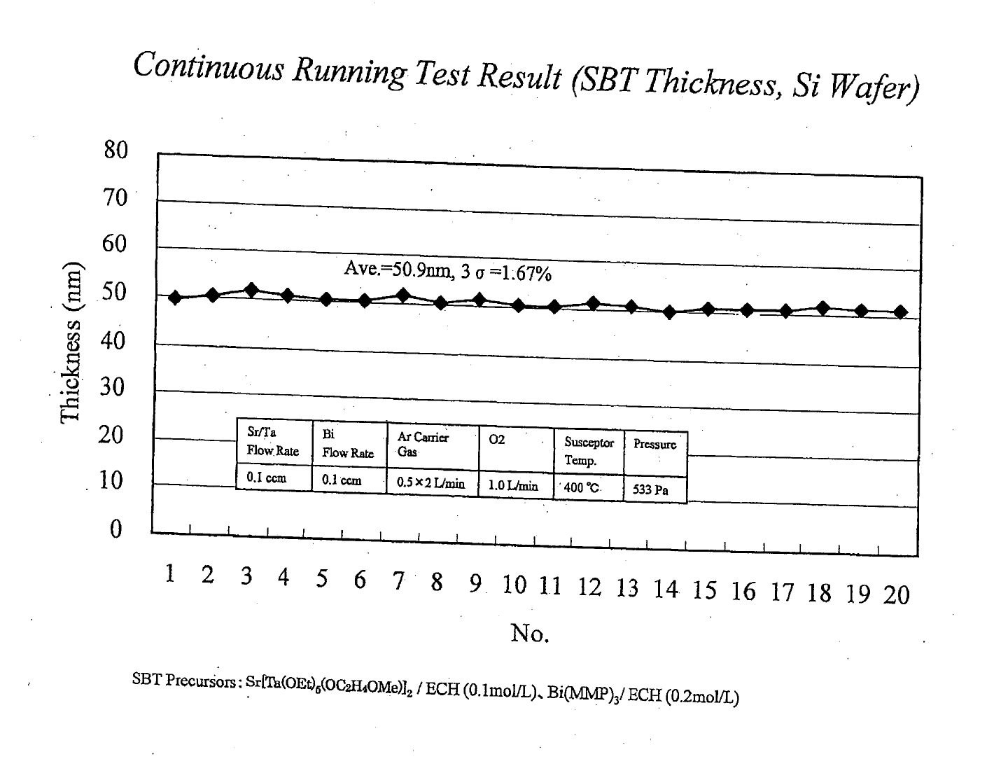

FIG. 2 is a diagram illustrating the result of an experiment that a solution-vaporization type CVD apparatus having the vaporizer for CVD of the first embodiment was continuously operated to form SBT thin films having a thickness of 50.9 nm on twenty silicon wafers under the same condition. According to this figure, when the SBT thin films were formed on the twenty silicon wafers by a continuous operation, it was confirmed that the SBT thin films without a variation in thickness were stably formed. That is, it was confirmed that the vaporizer for CVD of the first embodiment could stably form SBT thin films on the twenty silicon wafers without causing clogging in the vaporizer.

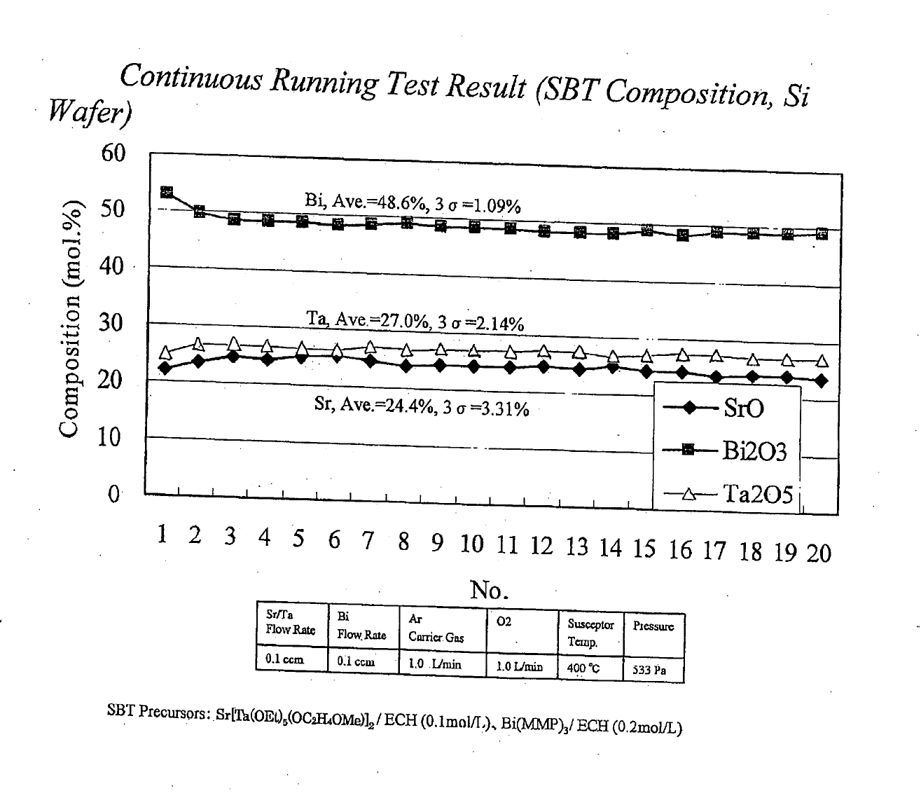

FIG. 3 is a diagram illustrating the result of an experiment that SBT thin films were formed on twenty silicon wafers by continuously operating the solution-vaporization type CVD apparatus, and the compositions of Bi, Ta, and Sr in the SBT film on each wafer were measured. According to the figure, it was confirmed that the SBT thin films having stable compositions of Bi, Ta, and Sr could be formed on the twenty silicon wafers.

As a result of conducting an experiment that the solution-vaporization type CVD apparatus having the vaporizer for CVD of the first embodiment was continuously operated to form an SBT thin film on a step, or in a recess portion or a groove was carried out, it was confirmed that the SBT thin film having a good step coverage could be formed. As a result of conducting an experiment that a high speed nonvolatile memory FeRAM utilizing the polarization phenomenon of SBT was fabricated by the solution-vaporization type CVD apparatus, it was possible to confirm that an extremely superior polarization characteristic of an SBT thin film was obtained.

What is claimed is:

1. A vaporizer for CVD comprising:
a dispersion unit which disperses a plurality of raw-material solutions into a carrier gas in a fine particulate or misty form;
a plurality of raw-material-solution passages which respectively supply said plurality of raw-material solutions, separately from one another, to said dispersion unit;
a carrier gas passage which supplies said carrier gas to said dispersion unit separately from each of said plurality of raw-material solutions;
a vaporization unit which vaporizes said plurality of raw-material solutions dispersed by said dispersion unit; and
an orifice which is connected to said vaporization unit and said dispersion unit and through which said plurality of raw-material solutions dispersed by said dispersion unit are introduced into said vaporization unit.

2. The vaporizer for CVD according to claim 1, wherein
said dispersion unit is disposed between said orifice and individual leading ends of said plurality of raw-material-solution passages, and
said orifice has a diameter smaller than a diameter of each of said plurality of raw-material-solution passages and a diameter of said carrier gas passage.

3. The vaporizer for CVD according to claim 1 or 2, wherein when said raw-material solutions are vaporized, said vaporization unit becomes a depressurized state, and said dispersion unit becomes a pressurized state.

4. A vaporizer for CVD comprising:
a plurality of raw-material-solution pipes which respectively supply a plurality of raw-material solutions separately from one another;
a carrier gas pipe which is disposed in such a manner as to surround exteriors of said plurality of raw-material-solution pipes and allows a pressurized carrier gas to flow to said exterior of each of said plurality of raw-material-solution pipes;
an orifice provided in a leading end of said carrier gas pipe and spaced away from leading ends of said plurality of raw-material-solution pipes;
a vaporization tube connected to said leading end of said carrier gas pipe and led to an interior of said carrier gas pipe via said orifice; and heating means for heating said vaporization tube.

5. The vaporizer for CVD according to claim 4, wherein said carrier gas and said plurality of raw-material solutions are mixed between said orifice in said carrier gas pipe and said leading ends of said plurality of raw-material-solution pipes, said plurality of raw-materials are dispersed into said carrier gas in a fine particulate or misty form, said dispersed fine particulate or misty raw-material solutions are introduced into said vaporization tube through said orifice and heated to vaporize by said heating means.

6. The vaporizer for CVD according to claim 4 or 5, wherein said orifice has a diameter smaller than a diameter of each of said plurality of raw-material-solution pipes and a diameter of said carrier gas pipe.

7. The vaporizer for CVD according to any one of claims 1 to 6, wherein
said plurality of raw-material solutions are a mixture of Sr[Ta(OEt)₅(OC₂H₄OMe)]₂ and a solvent and a mixture of Bi(MMP)₃ and a solvent, and
said carrier gas is an argon gas or a nitrogen gas.

8. A solution-vaporization type CVD apparatus comprising said vaporizer for CVD of any one of claims 1 to 7.

9. A solution-vaporization type CVD apparatus comprising:
said vaporizer for CVD of any one of claims 4 to 6; and
a reaction chamber connected to said vaporization tube,
wherein deposition is carried out with said plurality of raw-material solutions vaporized in said vaporization tube.

10. A vaporization method for CVD comprising:
supplying a plurality of raw-material solutions and a carrier gas to a dispersion unit separately from one another;
mixing said plurality of raw-material solutions and the carrier gas in said dispersion unit and dispersing said plurality of raw-material solutions into said carrier gas in a fine particulate or misty form; and
vaporizing said raw-material solutions by adiabatic expansion immediately after dispersion.

11. The vaporization method for CVD according to claim 10, wherein said raw-material solutions are dispersed in a fine particulate or misty form within one second after mixture of said raw-material solutions.
